(19) United States
(12) Patent Application Publication
(10) Pub. No.: US 2006/0078759 A1
(43) Pub. Date: Apr. 13, 2006

(54) Organic electroluminescent device

(76) Inventors: Hye-In Jeong, Suwon-Si (KR); Ok-Keun Song, Suwon-si (KR); Young-Mo Koo, Suwon-si (KR); Tae-Shick Kim, Suwon-si (KR)

Correspondence Address: H.C. PARK & ASSOCIATES, PLC, 8500 LEESBURG PIKE, SUITE 7500, VIENNA, VA, 22182, US

(21) Appl. No.: 11/191,017

(22) Filed: Jul. 28, 2005

(30) Foreign Application Priority Data
Oct. 11, 2004 (KR) 10-2004-0081112

(51) Int. Cl. H01L 51/54; H05B 33/14

(52) U.S. Cl. 428/690; 428/917; 313/504; 313/506

(57) ABSTRACT

An organic electroluminescent device comprises a first electrode, a hole transport layer comprising a hole transporting material and an blue emission material formed on the first electrode, an emission layer formed on the hole transport layer, and a second electrode formed on the emission layer. The hole transport layer comprising the blue emission material and the hole transporting material provides the organic electroluminescent device with a longer lifespan while maintaining luminous efficiency, a low driving voltage, and an improved color coordinate.

### CROSS REFERENCE TO RELATED APPLICATION

This application claims priority to and the benefit of Korean Patent Application No. 10-2004-0081112, filed on Oct. 11, 2004, in the Korean Intellectual Property Office, the disclosure of which is incorporated herein in its entirety by reference.

### BACKGROUND OF THE INVENTION

1. Field of the Invention

The present invention relates to an organic electroluminescent device, and more particularly to an organic electroluminescent device with a long lifespan.

2. Description of the Related Art

Organic electroluminescent devices are self emissive which means that when a voltage is applied to a fluorescent or phosphorescent organic layer, electrons and holes combine in the organic layer to emit light. Organic electroluminescent devices have many advantages including being lightweight, easy to manufacture, and having high resolution and wide viewing angles. Further, organic electroluminescent devices can display moving pictures with high color purity and require low power consumption and a low driving voltage. These advantages make organic electroluminescent devices suitable for use in portable electronic devices.

Generally, in order to improve the efficiency and decrease the driving voltage, an organic electroluminescent device includes, in addition to an emission layer, an electron transport layer, a hole transport layer, for example, which are all organic layers.

In an organic electroluminescent device, a blue emission material has a shorter lifespan than a red or green emission material. Therefore, an increase in the lifespan of the blue emission material may increase an organic electroluminescent device's lifespan.

### SUMMARY OF THE INVENTION

The present invention provides an organic electroluminescent device with a longer lifespan.

Additional features of the invention will be set forth in the description which follows, and in part will be apparent from the description, or may be learned by practice of the invention.

The present invention discloses an organic electroluminescent device comprising a first electrode and a hole transport layer that comprises a hole transporting material and a blue emission material and is formed on the first electrode. The device further comprises an emission layer that is formed on the hole transport layer and a second electrode that is formed on the emission layer.

It is to be understood that both the foregoing general description and the following detailed description are exemplary and explanatory and are intended to provide further explanation of the invention as claimed.

### BRIEF DESCRIPTION OF THE DRAWING

The accompanying drawing, which is included to provide a further understanding of the invention and is incorporated in and constitute a part of this specification, illustrates embodiments of the invention and together with the description serves to explain the principles of the invention.

FIG. 1 illustrates a structure of an organic electroluminescent device according to an exemplary embodiment of the present invention.

### DETAILED DESCRIPTION OF THE ILLUSTRATED EMBODIMENTS

An organic electroluminescent device according to an embodiment of the present invention includes a hole transport layer that is doped with 5 wt % to 20 wt % of a blue emission material based on the weight of the hole transport layer. This allows the energy difference between the hole transport layer and an emission layer to be adjusted to within a desirable range. Emission occurs from both the hole transport layer and the emission layer such that the emission region is extended. Due to these advantages, the organic electroluminescent device according to an embodiment of the present invention has a longer lifespan than an organic electroluminescent device with a conventional hole transport layer.

The emission layer may comprise an emission material that is used to emit blue, green, white, yellow, or orange light. Particularly, when the emission layer is composed of an emission material that is also used to form the hole transport layer, the lifespan of the organic electroluminescent device increases.

When the concentration of the blue emission material in the hole transport layer is less than 5 wt % based on 100 wt % of the hole transport layer, an increase in the lifespan is negligible. When the concentration of the blue emission material is more than 20 wt % based on 100 wt % of the hole transport layer, the lifespan of the organic electroluminescent device increases, but the efficiency of the organic electroluminescent device decreases.

The blue emission material has a maximum absorption wavelength (λmax) range of 420 nm to 480 nm. Examples of the blue emission material may include, but are not limited to Spiro-DPVBi, Flrpic, CzTT, Anthracene, TPB, PPCP, DST, TPA, OXD-4, BBOT, AZM-Zn, a compound (A) and a compound (B) which are represented by the following formulas, IDE120, and BH-013X (from Idemitz), which is an aromatic hydrocarbon compound with a naphthalene moiety.

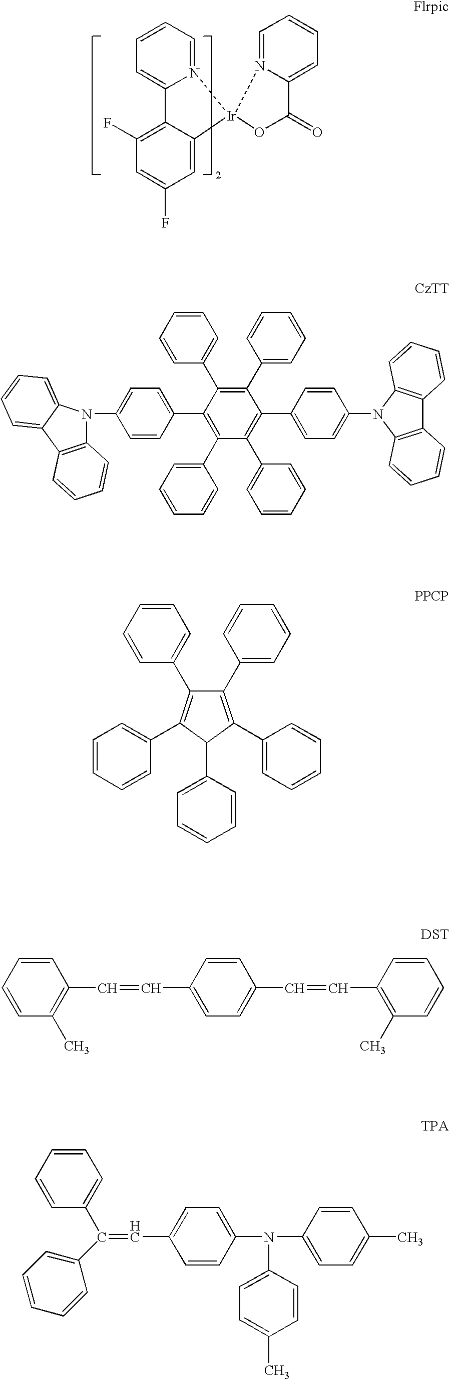

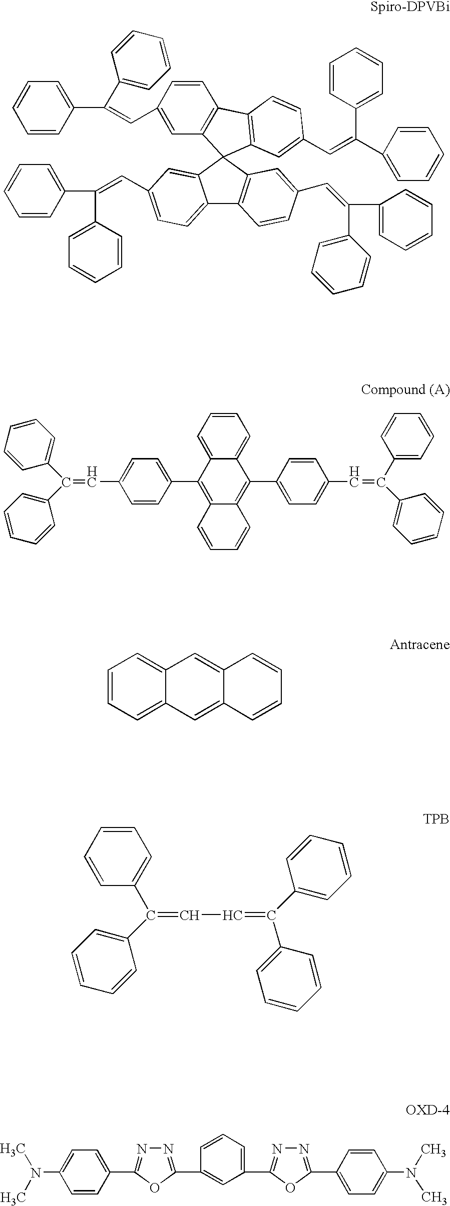

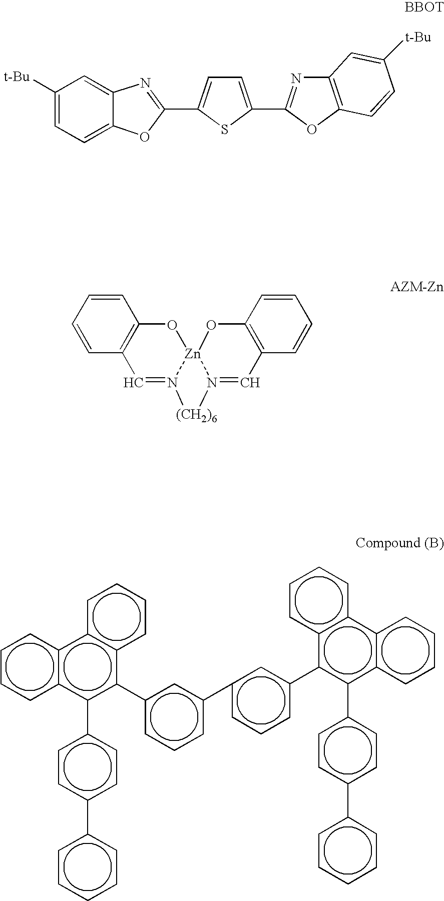

In addition, the compounds disclosed in Japanese Patent Laid-Open Publication 2000-192028, 2000-191560, 2000-48955, and 2000-7604, Japanese Patent No. hei. 10-11063, and U.S. Pat. No. 6,591,636, all of which are incorporated into by the present invention by reference, can be used as the blue emission material.

The blue emission material may also comprise an anthracene derivative that can emit blue light with high luminescence, high luminous efficiency, and high color purity.

The hole transport material may comprise N,N′-bis(3-methylphenyl)-N,N′-diphenyl-[1,1-biphenyl]-4,4′-diamine(TPD), N,N′-di(naphthalene-1-yl)-N,N′-diphenylbenzidine, N,N′-di(naphthalene-1-yl) -N,N′-diphenyl-benxidine (α-NPD), N,N′-diphenyl-N,N′-bis(1-naphthyl)-(1,1′-biphenyl)-4,4′-diamine (NPB), IDE320 (from Idemitz), or the mixture thereof, for example. The hole transport layer may be about 100 Å to 400 Å thick.

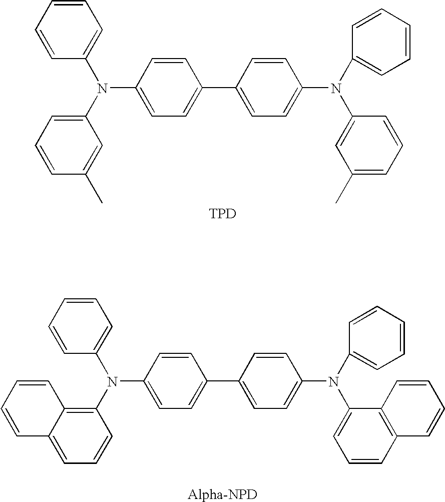

When the hole transport layer is less than 100 Å thick, the hole transporting ability deteriorates due to the small thickness. When the hole transport layer is more than 400 Å thick, the driving voltage increases.

A method for manufacturing an organic electroluminescent device according to an exemplary embodiment of the present invention will now be described with reference to FIG.

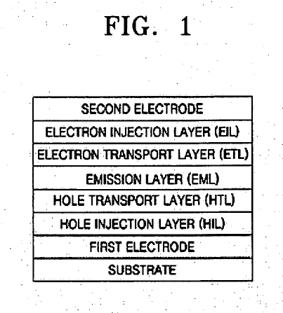

As shown in FIG. 1, an upper surface of the substrate is coated with a first electrode material to form a first electrode or anode. The substrate may be any material that is typically used in a conventional organic electroluminescent device such as glass or a transparent plastic that is waterproof, has a smooth surface, and can be easily treated. The first electrode material may be transparent and highly conductive. Examples of the anode material may include, but are not limited to Indium Tin Oxide (ITO), Indium Zinc Oxide (IZO), SnO₂, ZnO, and the like.

A hole injection layer is optionally deposited on the anode. The hole injection layer is formed by vacuum-thermal depositing a hole injection layer material on the anode, or by spin-coating the anode with the hole injection layer material. The hole injection layer may be about 300 Å to 1500 Å thick. When the hole injection layer is less than 300 Å thick, the lifespan and reliability of the organic electroluminescent device decrease. In addition, particularly for passive matrix (PM) organic electroluminescent devices, a resolution short may occur, which is undesirable. When the hole injection layer is greater than 1500 Å thick, the driving voltage increases.

The hole injection layer material may comprise copper phthalocyanine (CuPc), a starburst-type amines such as TCTA, m-MTDATA, H1406 (from Idemitz), for example.

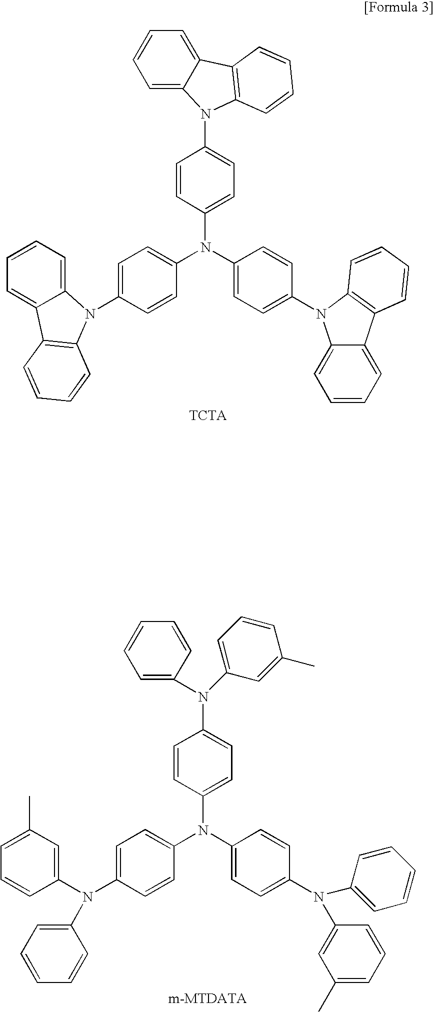

After forming the hole injection layer, a hole transport layer is formed by vacuum-thermal depositing a hole transporting material and a blue emission material on the hole injection layer, or by spin-coating the hole injection layer with a hole transporting material and a blue emission material.

Then an emission layer is formed on the hole transport layer. The emission layer may comprise an emission material that emits light of any color such as yellow, orange, green, blue, red, white, and the like. That is, the emission layer may have any wavelength.

A green emission layer may comprise Alq3 doped with a Coumarin-type dopant. A blue emission layer may comprise the same material used to form the hole transport layer. A red emission layer may comprise Alq3 doped with DCJTB, or be formed by codepositing Alq3 and rubrene and doping the resulting compound with a dopant.

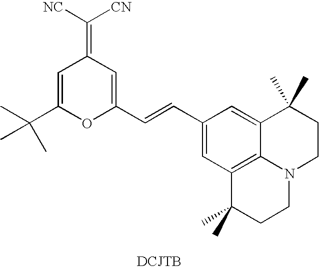

Such a Coumarin-type dopant may be C314S, C343S, C7, C7S, C6, C6S, C314T, or C545T. The concentration of the Coumarin-type dopant may be about 0.2 wt % to 3 wt % based on the weight of the material comprising the emission layer. When less than 0.2 wt % of the dopant is added, the efficiency deteriorates. When more than 3 wt % of the dopant is added, the lifespan of the resulting device decreases.

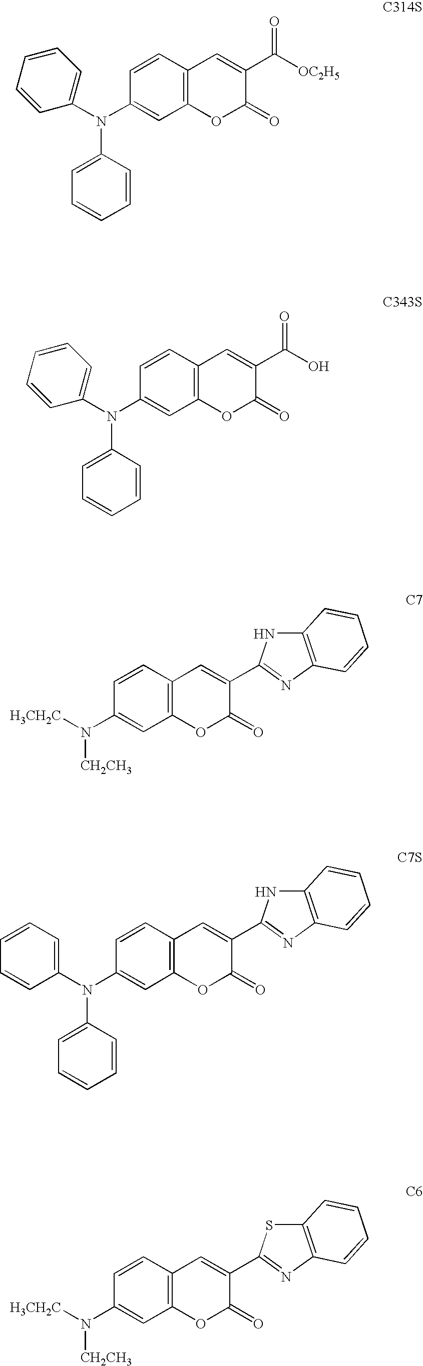

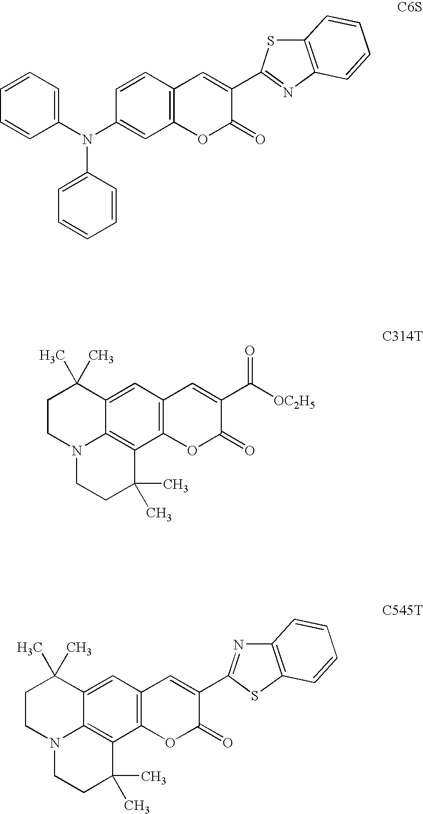

A hole blocking layer (not shown in FIG. 1) may optionally be formed on the emission layer. The hole blocking layer may be formed by vacuum-depositing a hole blocking material on the emission layer or by spin-coating the emission layer with the hole blocking material. The hole blocking material may have electron transporting ability and a greater ionization potential than the emission material. The hole blocking material may include, but is not limited to bis(2-methyl-8-quinolato)-(p-phenylphenolato)-aluminum (Balq), bathocuproine(BCP) and tris(N-arylbenzimidazole)(TPBI). The hole blocking layer may be about 30 Å to 70 Å thick. When the hole blocking layer is less than 30 Å thick, the hole blocking ability diminishes. When the hole blocking layer is more than 70 Å thick, the driving voltage increases.

An electron transport layer may be formed by vacuum-depositing an electron transporting material on the hole blocking layer or by spin-coating the hole blocking layer with the electron transporting material. The electron transporting material may comprise Alq3, but is not limited thereto. The electron transport layer may be about of 150 Å to 600 Å thick. When the electron transport layer is less than 150 Å thick, the electron transporting ability decreases. When the electron transport layer is more than 600 Å thick, the driving voltage increases.

An electron injection layer may optionally be formed on the electron transport layer. The electron injection layer may comprise LiF, NaCl, CsF, Li₂O, BaO, or Liq, for example. The electron injection layer may be about 5 Å to 20 Å thick. When the electron injection layer is less than 5 Å thick, the electron injecting ability decreases. When the electron injection layer is more than 20 Å thick, the driving voltage increases.

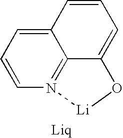

Subsequently, a cathode metal is vacuum-thermal deposited on the electron injection layer to form a second electrode. The second electrode metal may comprise Li, Mg, Al, Al—Li, Ca, Mg—In, or Mg—Ag, for example.

The organic electroluminescent device according to an embodiment of the present invention includes an anode, a hole injection layer, a hole transport layer, an emission layer, an electron transport layer, an electron injection layer, and a cathode. One or two additional intermediate layers can optionally be formed. In addition, the organic electroluminescent device may further comprise an electron blocking layer.

The present invention will now be described in further detail with reference to the following examples. The following examples are for illustrative purposes only and are not intended to limit the scope of the present invention.

### EXAMPLE 1

An ITO glass substrate (Coming surface resistance: 15 Ω/cm² thickness: 1200 Å), was cut to a size 50 mm×50 mm×0.7 mm to form the anode. The resulting glass substrate was cleaned in an ultrasonic cleaner in isopropyl alcohol for 5 minutes, cleaned in an ultrasonic cleaner in pure water for 5 minutes, and cleaned using UV light and ozone for 30 minutes.

Next, IDE406 (from Idemitz) was vacuum-deposited on the glass substrate to form a 600 Å thick hole injection layer. Subsequently, 85 wt % of N,N′-diphenyl-N,N′-bis(1-naphthyl)-(1,1′-biphenyl)-4,4′-diamine (NPB), and 15 wt % of BH-013X (from Idemitz), which is an aromatic hydrocarbon compound with a naphthalene moiety that is used as a blue emission host, was vacuum-deposited on the hole injection layer to form a 150 Å thick hole transport layer

Then, IDE140 (from Idemitz) was doped with BD-102 (from Idemitz) to form a 300 Å thick emission layer on the hole transport layer.

Subsequently, Alq3 was deposited on the emission layer to form a 250 Å thick electron transport layer

Finally, LiF 10 Å used as an electron injection layer and A1 1000 Å used as a cathode were sequentially vacuum-deposited on the electron transport layer to form a LiF/Al electrode. Thus, an organic electroluminescent device was fabricated.

### EXAMPLE 2

An organic electroluminescent device was fabricated in the same manner as in Example 1, except that a pure blue emission layer was formed by depositing 97 wt % of IDE140 (from Idemitz) doped with 3 wt % of BD-52 (from Idemitz) to a thickness of about 300 Å on the hole transport layer. In this case, IDE140 and BD-52 were used as a host and a dopant, respectively.

### EXAMPLE 3

An organic electroluminescent device was fabricated in the same manner as in Example 1, except that a green emission layer was formed by depositing 99 wt % of Alq3 doped with 1 wt % of C 6 to a thickness of about 400 Å on the hole transport layer. In this case, Alq3 and C 6 were used as a host and a dopant, respectively.

### EXAMPLE 4

An organic electroluminescent device was fabricated in the same manner as in Example 1, except that a red emission layer was formed by depositing 99 wt % of Alq3 doped with 1 wt % of DCJTB to a thickness of about 400 Å on the hole transport layer. In this case, Alq3 and DCJTB were used as a host and a dopant, respectively.

### COMPARATIVE EXAMPLE 1, COMPARATIVE EXAMPLE 2, COMPARATIVE EXAMPLE 3, and COMPARATIVE EXAMPLE 4

Organic electroluminescent devices were manufactured in the same manner as in Example 1, Example 2, Example 3, and Example 4, respectively, except that the hole transport layers comprised only NPB.

The initial characteristics and half-life of the organic electroluminescent devices of Example 1, Example 2, Example 3, Example 4, Comparative Example 1, Comparative Example 2, Comparative Example 3, and Comparative Example 4, were measured. The results for Example 1 and Comparative Example 1 are shown in Table 1.

1) Initial Characteristics

Luminance was measured using BM5A (from Topcon Co.), and a driving voltage was measured using KEITHLEY 236 (Keithley Instruments, Inc.). The current densities applied to the organic electroluminescent devices were in the range of 10 mA/cm² to 100 mA/cm² and increased by 10 mA/cm². At least nine data points were obtained for each device. The test was performed more than twice, and the initial characteristics exhibited excellent reproducibility with a deviation of 5%.

2) Half-Life

The half-life of the device was measured using two methods. In one method, when the current density was fixed at DC 50 mA/cm², the lifespan was measured over time. In the other method, current pulses with equal current densities were applied and the change of lifespan was observed until lifespan was reduced to half-life. These tests were performed on at least three devices, each having the same structure, to confirm the reproducibility of the results.

TABLE 1

| | | Half-life | Half-life |
|---|---|---|---|
| | Initial Characteristics | (DC @50 | (Pulse @900 |
| | (DC @100 mA/cm²) | mA/cm²) | mA/cm²) |
| Example 1 | 9.2 V, 10.97 cd/A, | 1,100 hrs | 2,300 hrs |
| | 3.27 lm/W | | |
| | (0.136, 0.271) | | |
| Comparative | 9.2 V, 10.97 cd/A, | 750 hrs | 1,500 hrs |
| Example 1 | 3.27 lm/W | | |
| | (0.136, 0.271) | | |

Referring to Table 1, the organic electroluminescent device of Example 1 had a longer half-life than the organic electroluminescent device of Comparative Example 1.

The organic electroluminescent devices according to Example 2, Example 3, and Example 4 had initial characteristics and lifespans similar to those of the organic electroluminescent device of Example 1.

Thus, the results demonstrate that an organic electroluminescent device according to the present invention that includes a hole transport layer comprising a blue emission material as well as a hole transporting material. Such an organic electroluminescent device has a longer lifespan while maintaining luminous efficiency, a low driving voltage, and an improved color coordinate.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An organic electroluminescent device, comprising:
a first electrode;
a hole transport layer comprising a hole transporting material and a blue emission material formed on the first electrode;
an emission layer formed on the hole transport layer; and
a second electrode formed on the emission layer.

2. The organic electroluminescent device of claim 1,
wherein the hole transport layer comprises 80 wt %-95 wt % of the hole transporting material and 5 wt %-20 wt % of the blue emission material.

3. The organic electroluminescent device of claim 1, wherein the blue emission material has a maximum absorption wavelength of about 420 nm to 480 nm.

4. The organic electroluminescent device of claim 1,
wherein the blue emission material comprises a compound selected from the group consisting of the compounds represented by the following chemical structures, and an aromatic hydrocarbon compound that has a naphthalene moiety:

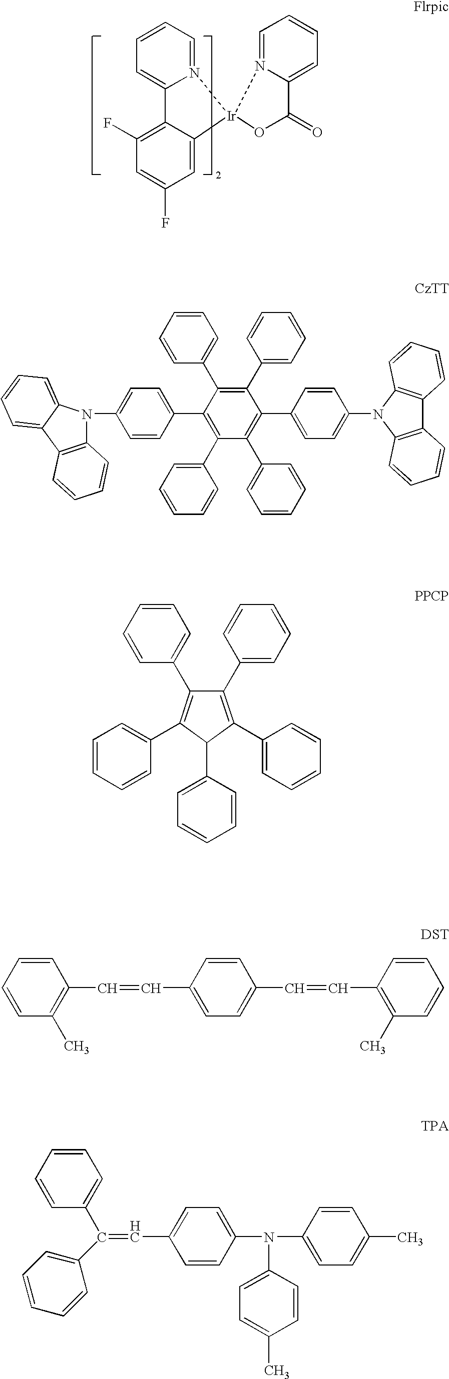

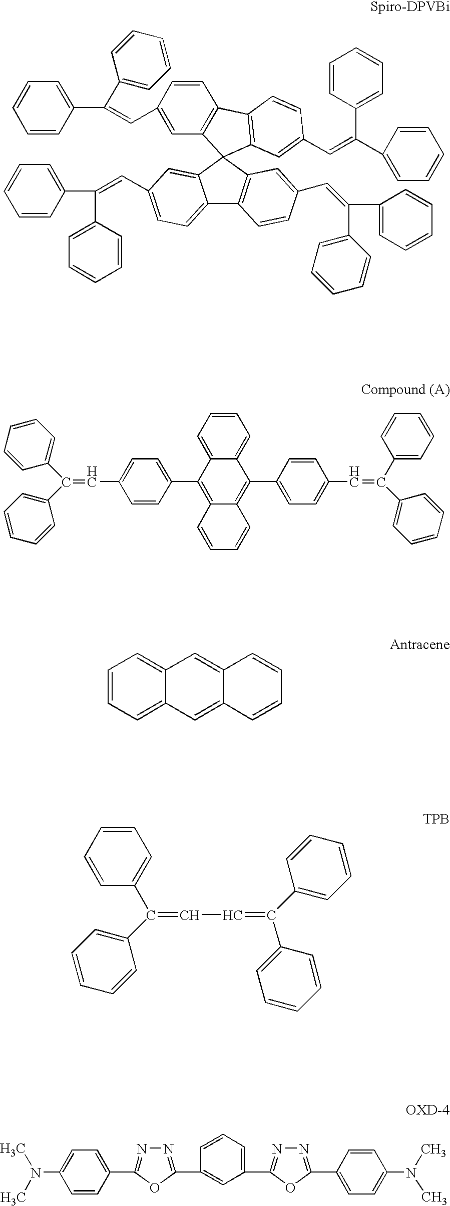

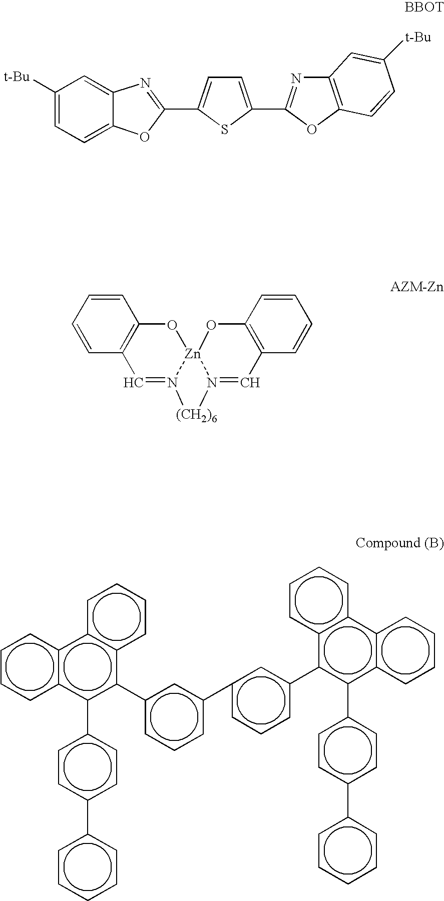

5. The organic electroluminescent device of claim 1,
wherein the hole transporting material comprises at least a compound selected from the group consisting of N,N′-bis(3-methylphenyl)-N,N′-diphenyl-[1,1-biphenyl]-4,4′-diamine, N, N′-di(naphthalene-1-yl)-N,N′-diphenylbenzidine, and N,N′-diphenyl-N,N′-bis(1-naphthyl)-(1,1′-biphenyl)-4,4′-diamine.

6. The organic electroluminescent device of claim 1,
wherein the emission layer comprises the blue emission material of the hole transport layer.

7. The organic electroluminescent device of claim 1, further comprising:
a hole injection layer formed between the first electrode and the hole transport layer.

8. The organic electroluminescent device of claim 1, further comprising:
at least one layer selected from the group consisting of a hole blocking layer, an electron transport layer, and an electron injection layer that is formed between the emission layer and the second electrode.

9. The organic electroluminescent device of claim 1,
wherein a hole transport layer comprises N,N′-diphenyl-N,N′-bis(1-naphthyl)-(1,1′-biphenyl)-4,4′-diamine (NPB) and an aromatic hydrocarbon compound having a naphthalene moiety.
